(19) United States
(12) Patent Application Publication
(10) Pub. No.: US 2026/0297738 A1
(43) Pub. Date: Oct. 1, 2026

(54) SEALING SYSTEM FOR A REACTOR SYSTEM

(71) Applicant: ASM IP Holding B.V., Almere (NL)

(72) Inventors: Yeonsu Rhee, Phoenix, AZ (US); Shuaidi Zhang, Chandler, AZ (US); Todd Robert Dunn, Cave Creek, AZ (US); Shubham Garg, Gilbert, AZ (US)

(21) Appl. No.: 19/630,752

(22) Filed: Mar. 27, 2026

Related U.S. Application Data
(60) Provisional application No. 63/781,552, filed on Apr. 1, 2025.

(51) Int. Cl. C23C 16/44; C23C 16/455; C23C 16/46

(52) U.S. Cl. CPC C23C 16/4409; C23C 16/45591; C23C 16/46

(57) ABSTRACT

A reactor can comprise a reaction chamber volume enclosed within a reaction chamber; a susceptor configured to translate up and down within the reaction chamber; a reaction space above, and a lower chamber space below, the susceptor within the reaction chamber volume; and/or a sealing system causing the reaction space and the lower chamber space to be substantially fluidly separate. The sealing system can comprise a spacer plate surrounding the susceptor; and/or a seal device coupled to and/or engaged with the susceptor and the spacer plate, wherein the seal device comprises a base ring coupled to the susceptor and a spring coupled to the base ring. The spring can have a spring bias, facilitating creation of a substantial seal between the spacer plate and the susceptor, causing the reaction space and the lower chamber space to be substantially fluidly separate as the susceptor translates within the reaction chamber.

### CROSS-REFERENCE TO RELATED APPLICATIONS

This application is a nonprovisional of, and claims priority to and the benefit of, U.S. Provisional Patent Application No. 63/781,552, filed Apr. 1, 2025 and entitled “SEALING SYSTEM FOR A REACTOR SYSTEM,” which is hereby incorporated by reference herein.

### FIELD

The present disclosure relates generally to a semiconductor processing or reactor system, and particularly to a reactor system and to components comprised therein, which allow sealing between an upper and lower volume within a reaction chamber.

### BACKGROUND

Reaction chambers can be used for a variety of processes during formation of electronic devices. For example, reaction chambers can be used for depositing various material layers onto semiconductor substrates, etching materials, and/or cleaning surfaces. A substrate can be placed on a susceptor inside a reaction chamber. Both the substrate and the susceptor can be heated to a desired substrate temperature set point. In an example process, one or more reactant gases can be passed over a heated substrate, causing the deposition of a thin film of material on the substrate surface.

Reaction chambers can comprise two spaces or volumes that are separated, for example, by a susceptor. Processing can occur in a reaction space or chamber of the two chambers (e.g., an upper chamber that is disposed vertically above a lower chamber). During operation of a reactor system comprising two chambers separated by a susceptor, contaminants may undesirably transfer from the reaction space to the other chamber (e.g., from the upper chamber to the lower chamber), or vice versa. Therefore, systems and methods for providing a seal between the two volumes within the reaction chamber (e.g., to at least partially fluidly separate the two chambers) may be desirable.

Any discussion of problems and solutions has been included in this disclosure solely for the purposes of providing a context for the present disclosure, and should not be taken as an admission that any or all of the discussion was known at the time the disclosure was made.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some examples, a reactor system is provided. The reactor system disclosed herein may facilitate at least partial sealing (e.g., substantial sealing) between two chambers or volumes within a reaction chamber of a reactor system.

In various examples, a reactor can comprise a reaction chamber volume enclosed within a reaction chamber; a susceptor configured to translate up and down along an axis within the reaction chamber; a reaction space above the susceptor within the reaction chamber volume; a lower chamber space below the susceptor within the reaction chamber volume; and/or a sealing system causing the reaction space and the lower chamber space to be substantially fluidly separate. The sealing system can comprise a spacer plate surrounding the susceptor; and/or a seal device coupled to and/or engaged with the susceptor and the spacer plate, wherein the seal device comprises a base ring coupled to the susceptor and a spring coupled to the base ring. The spring can have a bias toward a compressed position or an extended position, such that the spring bias facilitates creation of a substantial seal between the spacer plate and the susceptor, causing the reaction space and the lower chamber space to be substantially fluidly separate as the susceptor moves up and down within the reaction chamber.

In various examples, the sealing system can further comprise a flow control ring disposed around the susceptor and disposed between the susceptor and the spacer plate. The seal device can be disposed between the flow control ring and the spacer plate such that the seal device is coupled to the susceptor via the flow control ring. The substantial seal between the spacer plate and the susceptor can be facilitated by the spring bias between the flow control ring and the spacer plate. The seal device can be disposed between an upward-facing surface of the flow control ring and a downward-facing surface of the spacer plate. The spring can be biased toward the extended position, such that a downward force from the spring is applied to the flow control ring, which creates a downward force on the susceptor, such that a substantial seal is formed between the flow control ring and the susceptor, forming the substantially fluid separateness between the reaction space and the lower chamber space. The spring can be fixedly coupled to the base ring. The seal device can surround the susceptor, wherein the spring comprises a plurality of concertinaed plates comprising a first concertinaed plate and a terminal concertinaed plate, and wherein each concertinaed plate span between the flow control ring and the spacer plate.

The base ring can comprise a base inner diameter most proximate to the susceptor, wherein the spring comprises a spring inner diameter most proximate to the susceptor, wherein the base inner diameter can be more proximate to the susceptor than the spring inner diameter. The base ring can comprise a bottom surface disposed against the upward-facing surface of the flow control ring and a radially-inward surface disposed against an outer side surface of the flow control ring, wherein the base ring can further comprise a chamfer surface spanning between the bottom surface and the radially-inward surface of the base ring. The flow control ring can further comprise a ring chamfer surface spanning between the upward-facing surface and the outer side surface that can be complementary to the chamfer surface of the base ring. The base ring can comprise a top surface and a coupling protrusion protruding upward from the top surface, wherein the first concertinaed plate of the concertinaed plates is coupled to the coupling protrusion. The first concertinaed plate can comprise a flat end surface that is coupled to the coupling protrusion. The base ring can comprise a base inner diameter most proximate to the susceptor, wherein the coupling protrusion is disposed proximate the base inner diameter. The terminal concertinaed plate can be coupled to and/or or disposed against the spacer plate. The seal device can further comprise a second base ring coupled to the terminal concertinaed plate, such that the spring spans between the base ring and the second base ring. The second base ring can contact the spacer plate to create a substantial seal between the second base ring and the spacer plate. The base ring can have a mass that is at least three times a mass of the spring.

In various examples, a seal device for a reactor can comprise a base ring; and/or a spring fixedly coupled to and extending from the base ring, wherein the spring comprises a plurality of concertinaed plates spanning between a first concertinaed plate and a terminal concertinaed plate. The base ring can comprise a base inner diameter, and the spring can comprise a spring inner diameter, wherein the base inner diameter is more radially inward than the spring inner diameter. The base ring can comprise a bottom surface, a radially-inward surface, and a chamfer surface spanning between the bottom surface and radially-inward surface of the base ring. The base ring can comprise a top surface and a coupling protrusion protruding from the top surface, wherein the first concertinaed plate of the concertinaed plates can comprise a flat end surface that is coupled to the coupling protrusion.

In various examples, a sealing system for a reactor can comprise a spacer plate configured to surround a susceptor; a flow control ring configured to surround the susceptor and be disposed between the spacer plate and the susceptor; and/or a seal device. The seal device can comprise a base ring; and/or a spring fixedly coupled to and extending from the base ring, wherein the spring comprises a plurality of concertinaed plates comprising a first concertinaed plate and a terminal concertinaed plate, wherein the base ring and the spring span between an upward-facing surface of the flow control ring and a downward-facing surface of the spacer plate. The spring can comprise a spring bias to an extended position configured to create a substantial seal between the flow control ring and the spacer plate.

For the purpose of summarizing the disclosure and the advantages achieved over the prior art, certain objects and advantages of the disclosure have been described herein above. Of course, it is to be understood that not necessarily all such objects or advantages may be achieved in accordance with any particular example of the disclosure. Thus, for example, those skilled in the art will recognize that the examples disclosed herein can be carried out in a manner that achieves or optimizes one advantage or group of advantages as taught or suggested herein without necessarily achieving other objects or advantages as may be taught or suggested herein.

All of these examples are intended to be within the scope of the disclosure. These and other examples will become readily apparent to those skilled in the art from the following detailed description of certain examples having reference to the attached figures, the disclosure not being limited to any particular example(s) discussed.

### BRIEF DESCRIPTION OF THE DRAWING FIGURES

While the specification concludes with claims particularly pointing out and distinctly claiming what are regarded as examples of the disclosure, the advantages of examples of the disclosure may be more readily ascertained from the description of certain examples when read in conjunction with the accompanying drawings. Elements with the like element numbering throughout the figures are intended to be the same.

FIG. 1 is a schematic diagram of an exemplary reactor system, in accordance with various examples.

FIG. 2A is a schematic diagram of an exemplary reaction chamber with a susceptor disposed in a lower position, in accordance with various examples.

FIG. 2B is a schematic diagram of an exemplary reaction chamber with a susceptor disposed in a raised position, in accordance with various examples.

FIG. 3 illustrates a schematic diagram of a portion of a reaction chamber, in accordance with various examples.

FIG. 4 illustrates a sealing device for a reactor system, in accordance with various examples.

FIGS. 5A and 5B illustrate sealing devices for a reactor system, in accordance with various examples.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of examples of methods, structures, devices, and systems provided below is merely exemplary and is intended for purposes of illustration only—the following description is not intended to limit the scope of the disclosure or the claims. Moreover, recitation of multiple examples having stated features is not intended to exclude other examples having additional features or other examples incorporating different combinations of the stated features. For example, various examples are set forth as embodiments and may be recited in the dependent claims. Unless otherwise noted, the examples or components thereof may be combined or may be applied separately from each other. Methods may include the disclosed steps in any suitable and/or desired order or combination. The illustrations presented herein are not meant to be actual views of any particular material, apparatus, structure, or device, but are merely representations that are used to describe examples of the disclosure.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the terms “includes,” “comprises,” “including,” and/or “comprising” specify the presence of stated features, integers, steps, processes, members, components, and/or groups thereof, but do not preclude the presence or addition of one or more other features, integers, steps, processes, members, components, and/or groups thereof. In this disclosure, any defined meanings do not necessarily exclude ordinary and customary meanings in some examples.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

In some examples, “film” refers to a layer extending in a direction perpendicular to a thickness direction. In some examples, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “contaminant” may refer to any unwanted material disposed within the reaction chamber that may affect the purity of a substrate disposed in the reaction chamber. The term “contaminant” may refer to, but is not limited to, unwanted deposits, metal and non-metal particles, impurities, and waste products, disposed within the reactor system or reaction chamber, or any portion thereof.

In this disclosure, any two numbers of a variable can constitute a workable range of the variable, any ranges indicated may include or exclude the endpoints, and all ranges and ratio limits disclosed herein may be combined. Additionally, any values of variables indicated (regardless of whether they are indicated with “about” or not) may refer to precise values or approximate values and include equivalents, and may refer to average, median, representative, majority, etc. in some examples. Unless specifically stated otherwise, references to “a,” “an,” and/or “the” may include one or more than one, and references to an item in the singular may also include the item in the plural. When referring to components of systems discussed herein, the term “coupled” refers to direct coupling or indirect coupling with other intervening elements, as appropriate. Unless otherwise indicated, the terms “first,” “second,” etc., and/or “primary,” “secondary,” etc., are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item. Further, reference to, e.g., a “first” item and a “second” item does not mean that there are no intervening items, and such intervening items may be present.

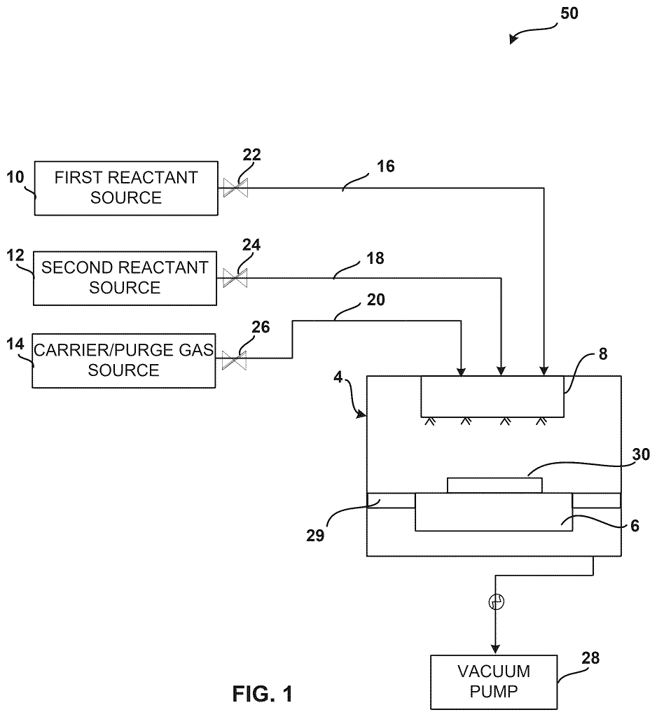

Reactor systems used for ALD, CVD, and/or the like, may be used for a variety of applications, including depositing and etching materials on a substrate surface. In various examples, with reference to FIG. 1, a reactor system 50 may comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16-20, and/or valves or controllers 22-26. System 50 may also comprise a vacuum source 28 fluidly coupled to the reaction chamber 4. Sealing members 29 may separate (e.g., at least partially separate fluidly) portions of a volume within reaction chamber 4.

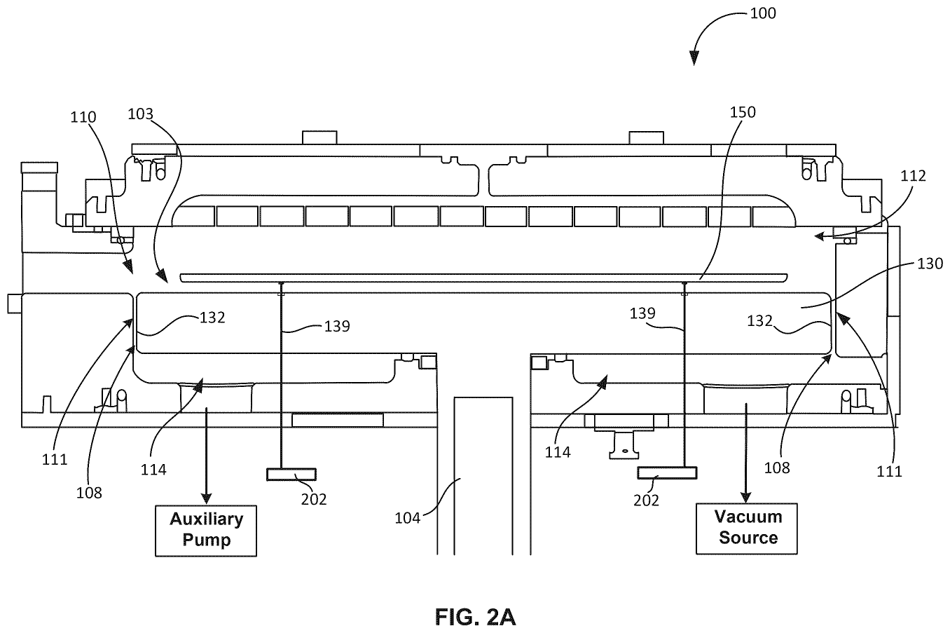

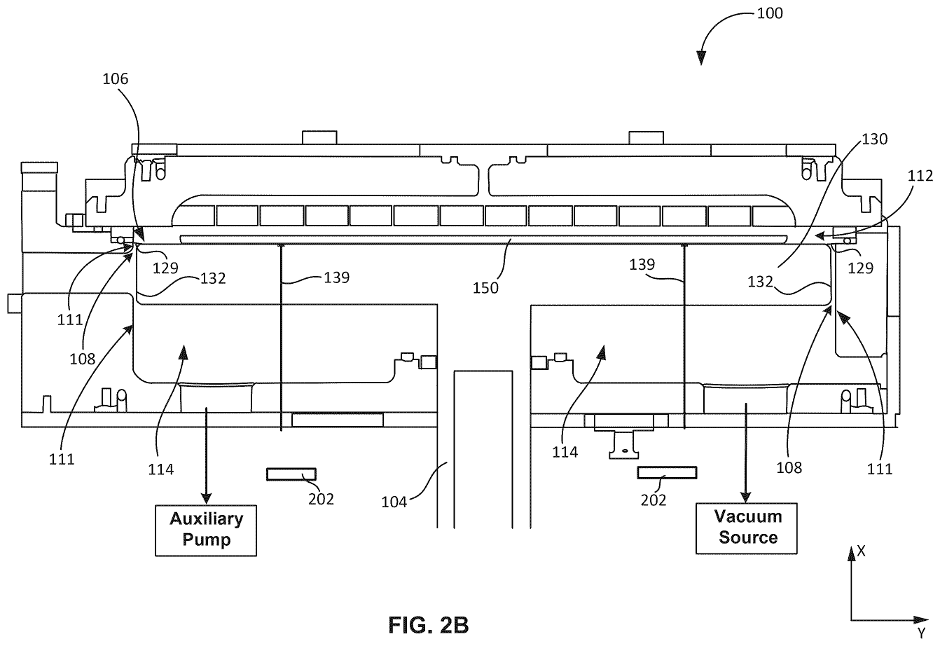

Turning to FIGS. 2A and 2B, the examples of the disclosure may include reactor systems and methods that may be utilized for processing a substrate within a reactor 100. In various examples, a reactor 100 may comprise a reaction chamber 110 for processing substrates. In various examples, reaction chamber 110 may comprise a reaction space 112 (i.e., an upper chamber), which may be configured for processing one or more substrates, and/or a lower chamber space 114 (i.e., a lower chamber). Lower chamber space 114 may be configured for the loading and unloading of substrates from the reaction chamber, and/or for providing a pressure differential between lower chamber space 114 and reaction space 112.

In various examples, substrate 150 and susceptor 130 may be movable relative to one another. For example, in various examples, lift pins 139 may be configured to allow substrate 150 to separate from susceptor 130, and to allow substrate 150 to be placed in contact with (i.e., to be supported by) susceptor 130. In various examples, susceptor 130 may move, for example via a susceptor elevator 104, up or down such that susceptor 130 moves relative to substrate 150. In various examples, lift pins 139 may move up or down, for example via lift pin elevators/platforms 202 such that substrate 150 moves relative to 130 susceptor. In various examples, susceptor 130 and/or lift pins 139 may be stationary while the other is moving. In various examples, susceptor 130 and/or lift pins 139 may be configured to move relative to the other.

In various examples, susceptor 130 may move from loading position 103 to processing position 106, thus moving substrate 150 into reaction space 112. Substrate 150 may be subsequently processed within the reaction chamber.

In various examples, reaction space 112 and lower chamber space 114 may be separated by susceptor 130 disposed in reaction chamber 110. In various examples, reaction space 112 and lower chamber space 114 may be substantially fluidly separate or isolated from one another. For example, a susceptor 130 can substantially fluidly separate reaction space 112 and lower chamber space 114 by creating at least a partial seal (i.e., at least restricting fluid flow) between susceptor 130 and a chamber sidewall 111 of reaction chamber 110 disposed proximate a susceptor outer side surface 132 of susceptor 130. That is, space 108 between susceptor 130 and chamber sidewall 111 may be minimized or eliminated such that there is little or no fluid movement between susceptor 130 and chamber sidewall 111. As used herein, “substantially fluidly separate,” “substantially sealed,” “substantial seal,” and/or other like phrases can mean a seal, the purpose of which is to decrease fluid movement across the seal as much as possible, such that any fluid passing (i.e., leaking) through the seal is not desired and/or measured (a complete seal being the objective, but practically, some fluid may leak through).

In various examples, to prevent or reduce fluid flow between susceptor 130 and chamber sidewall 111 (i.e., create a substantial seal therebetween), one or more sealing members (e.g., sealing members 129) may couple to susceptor 130 (e.g., from susceptor outer side surface 132) and/or chamber sidewall 111 of reaction chamber 110 to the other, creating at least a partial seal (i.e., a substantial seal) between susceptor 130 and chamber sidewall 111. Sealing members 129 can be diaphragms. The substantial seal of reaction space 112 from lower chamber space 114 can be desirable to prevent or reduce precursor gases, and/or other fluids, utilized in the processing of a substrate 150, from entering and/or contacting lower chamber space 114 of reaction chamber 110. For example, the precursor gases utilized for processing substrates in the reaction space can comprise corrosive deposition precursors, which can contact lower chamber space 114 producing unwanted deposits/contaminants/particles, which can in turn be reintroduced into reaction space 112 thereby providing a source of contamination to a substrate disposed in the reaction space.

In various examples, to create a substantial seal between the reaction space and lower chamber space, a reaction chamber can comprise a sealing system disposed between the susceptor and the chamber sidewall. For example, the sealing system in reaction chamber 110 can comprise sealing member 129 disposed between susceptor 130 and chamber sidewall 111 to create a substantial seal between reaction space 112 and lower chamber space 114.

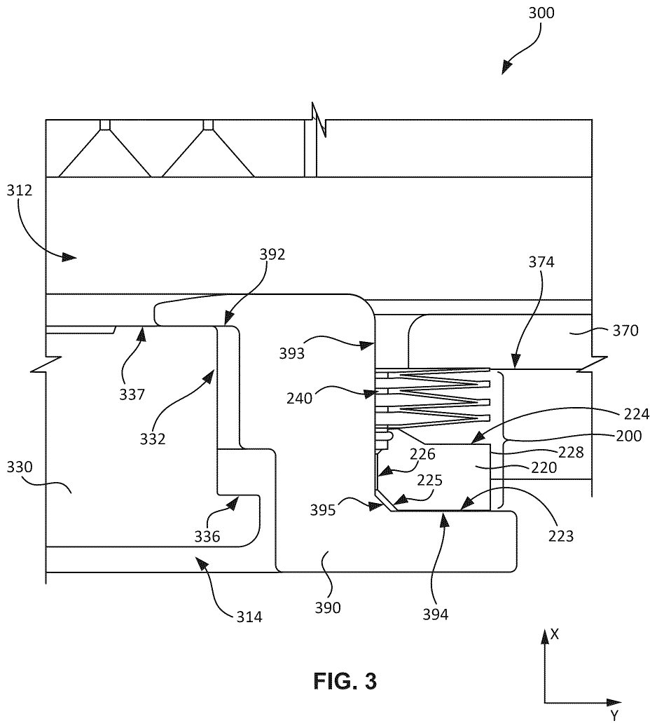

In various examples, a sealing system within a reaction chamber can comprise a spacer plate (e.g., spacer plate 370 in FIG. 3), at least a portion of which can be protruding from the chamber side wall into the reaction chamber volume. In various examples, the spacer plate can surround the susceptor (e.g., susceptor 330 in FIG. 3) in the reaction chamber. The spacer plate can couple with the susceptor (e.g., in response to the reaction chamber moving into or being disposed in a processing position (e.g., a raised position)). In various examples, the spacer plate can be in contact with and/or coupled directly to the susceptor (e.g., when the susceptor is in the raised or processing position). For example, a downward-facing surface of the spacer plate (e.g., surface 374 in FIG. 3) can couple with and/or contact an upward-facing surface of the susceptor (e.g., upward-facing surface 336 in FIG. 3). In various examples, the upward-facing surface of the susceptor that can engage the spacer plate may be the substrate support surface.

In various examples, a sealing system can comprise a flow control ring (e.g., flow control ring 390 in FIG. 3) disposed between the susceptor and the spacer plate. A flow control ring can be disposed around the susceptor, and can be configured to control fluid flow within a reaction chamber. For example, sealing member 129 in FIG. 1 can be a flow control ring. Thus, the susceptor can be coupled to and/or engaged with the spacer plate via the flow control ring. The reaction space and the lower chamber space can be substantially separated (fluidly and/or physically) by the susceptor, flow control ring, and/or spacer plate. For example, as shown in FIG. 3, flow control ring 390 can be disposed between spacer plate 370 and susceptor 330. Flow control ring 390 can comprise an upward-facing surface 394 that engages with (i.e., couples to and/or contacts) downward-facing surface 374 of spacer plate 370. Flow control ring 390 can comprise a downward-facing surface 392 that engages with (i.e., couples to and/or contacts) upward-facing surface 337 of susceptor 330. In various examples, the upward-facing surface of the susceptor with which flow control ring engages may be the substrate support surface. In various examples, at least a portion of a flow control ring can be disposed above at least a portion of the spacer plate, such that the flow control ring cannot translate below the spacer plate.

In various examples, a sealing system in a reaction chamber can comprise a seal device (e.g., seal device 200) disposed between and/or coupled to the spacer plate and the susceptor (e.g., where an upward-facing surface of the susceptor is configured to engage with a downward-facing surface of the spacer plate via the seal device). In various examples, a seal device may be disposed between and/or coupled to the spacer plate and the flow control ring in a sealing system for a reaction chamber (e.g., where a flow control ring is disposed between the susceptor and the spacer plate). In such examples, the seal device can be coupled to the susceptor via the flow control ring.

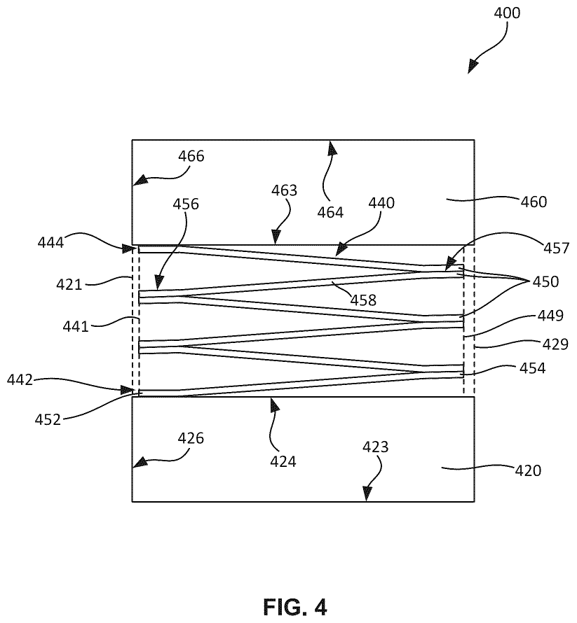

With reference to FIG. 4, in various examples, a seal device 400 can comprise a base ring 420 and a spring 440 coupled to base ring 420. Spring 440 can be removably or fixedly coupled to base ring 420. Spring 440 can be coupled to a top surface 424 of base ring 420. Base ring 420 can at least partially surround the susceptor and/or flow control ring, and can have an inner diameter 421 and an outer diameter 429. Inner diameter 421 can be a portion of base ring 420 most proximate the susceptor, and outer diameter 429 can be the portion of base ring 420 furthest from the susceptor. Inner diameter 421 can be aligned with at least a portion of a radially-inward surface 426 of base ring 420. Base ring 420 can comprise a height spanning between top surface 424 and a bottom surface 423. Bottom surface 423 can be disposed against an upward-facing surface of the susceptor or flow control ring. Radially-inward surface 426 of base ring 420 can be disposed proximate to and/or against an outer side surface of the susceptor or flow control ring.

In various examples, spring 440 can at least partially surround the susceptor and/or flow control ring, and can comprise a concertinaed plate stack (e.g., a bellows). The concertinaed plate stack can comprise one or more concertinaed plates 450. Concertinaed plates 450 can be integral and/or monolithic with one another, or concertinaed plates 450 can be separated plates coupled to one another. Each concertinaed plate 450 can span between an inner end 452 and an outer end 454, and between inner diameter 421 and outer diameter 429 of base ring 420. Inner end 452 of each concertinaed plate 450 can be the portion of the respective concertinaed plate 450 disposed most proximate to inner diameter 421 of base ring 420. Outer end 454 of each concertinaed plate 450 can be the portion of the respective concertinaed plate 450 disposed most proximate to outer diameter 429 of base ring 420. Inner end 452 of one concertinaed plate 450 can be coupled to an inner end 452 of another (an adjacent) concertinaed plate 450 in the concertinaed plate stack. Similarly, outer end 454 of one concertinaed plate 450 can be coupled to an outer end 454 of another (an adjacent) concertinaed plate 450 in the concertinaed plate stack. Concertinaed plates 450 can be (fixedly) coupled to one another in any suitable manner (e.g., welding, adhesive, fastener(s), and/or the like) to form the bellows.

Inner end 452 of each concertinaed plate 450 can comprise an inner flat end 456, and/or outer end 454 of each concertinaed plate 450 can comprise an outer flat end 457. The flat ends of the concertinaed plates 450 can facilitate coupling to other concertinaed plates 450 and/or base ring 420. That is, the flat ends provide a flat surface for coupling (e.g., between concertinaed plates 450 and/or to base ring 420), providing greater surface area for contacting and coupling between the respective components rather than concertinaed plates 450 forming a bellows or zigzag configuration without flat surfaces on the ends of concertinaed plates 450. The flat ends can comprise any suitable dimensions, such as having a length (between an inner diameter and outer diameter of each flat end) of about one millimeter (mm) (wherein “about” in this context means plus or minus 0.5 mm). The flat ends of concertinaed plates 450 can span in a direction that is substantially parallel with the surface of base ring 420 to which spring 440 is coupled, and/or substantially perpendicular to the direction of compression or expansion of spring 440 (“substantially” meaning plus or minus 10 degrees). A body 458 of each concertinaed plate 450 spans between the flat ends, and can be angled from the direction of the concertinaed plates 450 flat ends (the angle can change depending on the compression or extension of spring 440).

Spring 440 (the concertinaed plate stack) can span or protrude from base ring 420 (e.g., from top surface 424). Spring 440 can span (e.g., in the direction of compression or expansion of spring 440) between a first concertinaed plate 442 and a terminal concertinaed plate 444. First concertinaed plate 442 can be coupled to base ring 420 (e.g., to top surface 424 thereof). A first end of first concertinaed plate 442 can be coupled to base ring 420 in any suitable manner, such as by welding, adhesive, a fastener, and/or the like. The first end of first concertinaed plate 442 can be coupled to base ring 420 proximate to inner diameter 421, such that first concertinaed plate 442 spans from its first end toward outer diameter 429 of base ring 420. Coupling first concertinaed plate 442 proximate to inner diameter 421 of base ring 420 (and/or at or near inner diameter 441 of spring 440) can mitigate the potential for contamination by allowing less space in which particles or contaminants can flow as opposed to coupling first concertinaed plate 442 more proximate outer diameter 429 of base ring 420.

Spring 440 can comprise an inner diameter 441 (the portion of concertinaed plates 450 most proximate to the susceptor) and an outer diameter 449 (the portion of concertinaed plates 450 furthest from the susceptor). Inner diameter 441 of spring 440 can be radially outward of inner diameter 421 of base ring 420 (i.e., inner diameter 421 of base ring 420 can be smaller and more proximate the susceptor than inner diameter 441 of spring 440). Thus, base ring 420 can contact the susceptor and/or flow control ring by base ring 420 (or inner diameter 421 thereof) being disposed thereagainst, and the smaller inner diameter 421 of base ring 420 keeps inner diameter 441 of spring 440 separated from the susceptor and/or flow control ring. Thus, base ring 420, which can be a solid piece of material, can protect the more fragile spring 440 from being bumped or otherwise deformed or damaged by contact with other components of the reactor.

In various examples, seal device 400 can further comprise a second base ring 460. Second base ring 460 can be disposed opposite of base ring 420 with spring 440 spanning therebetween. Second base ring 460 can span radially from a radially-inward surface 466, which can be at least partially aligned with inner diameter 421 (and/or radially-inward surface 426 of base ring 420). Second base ring 460 can comprise a height spanning between top surface 464 and a bottom surface 463. Top surface 464 can contact and/or be disposed against a downward-facing surface of the spacer plate (e.g., in response the susceptor moving toward the raised position, which can cause spring 440 to compress). Radially-inward surface 466 of second base ring 460 can be disposed proximate to and/or against an outer side surface of the susceptor or flow control ring.

In various examples, a seal device may not comprise a second base ring 460. Thus, terminal concertinaed plate 444 (or flat end 456 thereof) can contact and/or be disposed against a downward-facing surface of the spacer plate (e.g., in response the susceptor moving toward the raised position, which can cause spring 440 to compress). Flat end 456 of terminal concertinaed plate 444 can facilitate more surface area of contact and thus a better seal (e.g., a substantial seal) with the spacer plate, as opposed to a smaller point of contact therebetween.

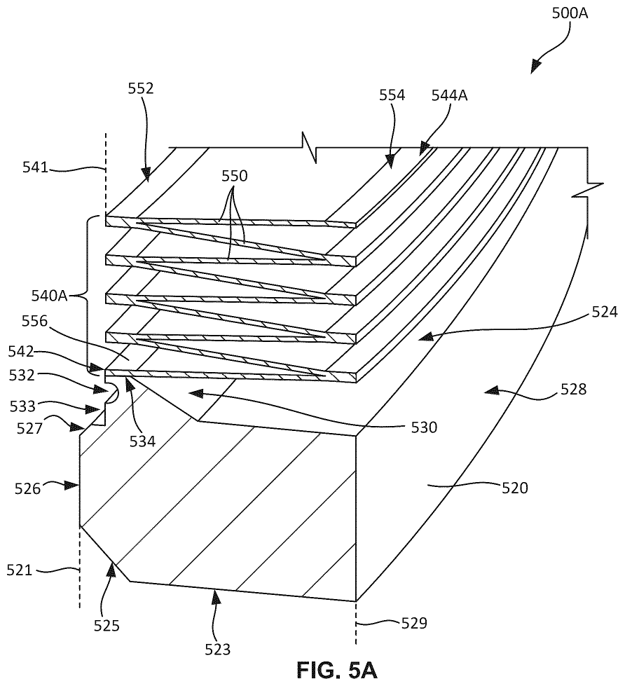

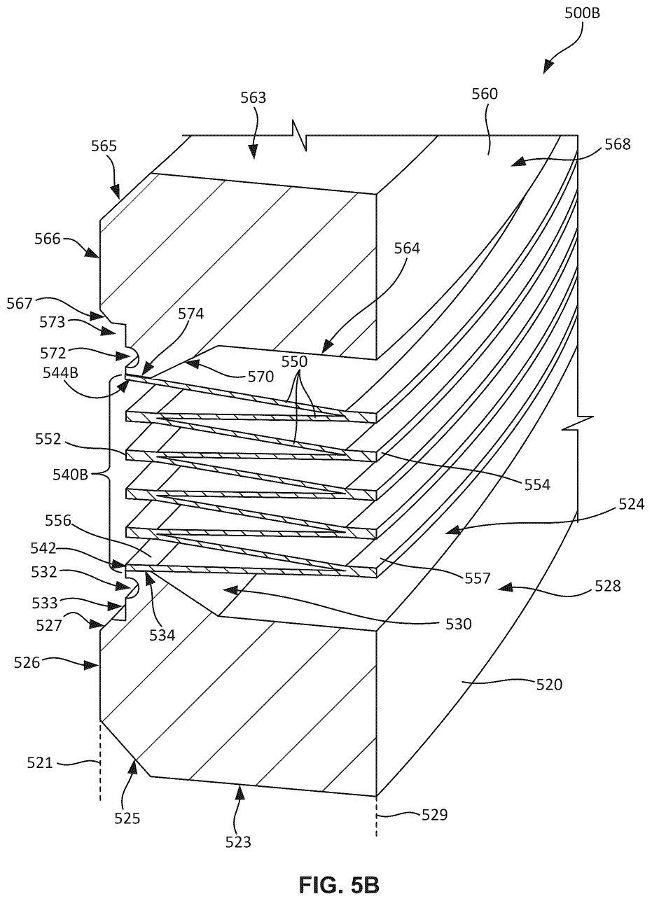

With additional reference to FIGS. 5A and 5B, additional examples of seal devices are depicted. Seal devices 500A and 500B depicted in FIGS. 5A and 5B, respectively, can have similar components to seal device 400 in FIG. 4. Therefore, the discussion of seal device 400 and its components can apply to seal devices 500A and 500B and its corresponding components, as appropriate. Base ring 520 (another example of base ring 420), can span radially between a radially-inward surface 526 and a radially-outward surface 528, and can comprise a height spanning between top surface 524 and a bottom surface 523. Bottom surface 523 can be disposed against an upward-facing surface of the susceptor or flow control ring. Radially-inward surface 526 of base ring 520 can be disposed proximate to and/or against an outer side surface of the susceptor or flow control ring. Radially-inward surface 526 of base ring 520 can at least partially define an inner diameter 521 of seal device 500A.

In various examples, base ring 520 can comprise a chamfer surface 525 spanning between bottom surface 523 and radially-inward surface 526. Chamfer surface 525 can be angled (i.e., an angled bridge) between bottom surface 523 and radially-inward surface 526. Chamfer surface 525 can be disposed at any suitable angle. For example, chamfer surface 525 can be disposed at an angle of about 45 degrees relative to the plane along which bottom surface 523 spans, and/or an angle of about 135 degrees relative to bottom surface 523. Chamfer surface 525 can be disposed at an angle of about 45 degrees relative to the plane along which radially-inward surface 526 spans, and/or an angle of about 135 degrees relative to radially-inward surface 526 (in this context, the term “about” means plus or minus 20 or 30 degrees). Chamfer surface 525 can be configured to provide a more gradual surface that can contact the susceptor or flow control ring (e.g., rather than a sharper corner between bottom surface 523 and radially-inward surface 526 that could cause scraping, chipping, or other damage to the susceptor or flow control ring). Accordingly, with momentary reference to FIG. 3, when seal device 200 (an example of seal device 500A) is being (removably) positioned between flow control ring 390 and spacer plate 370, base ring 220 can be disposed such that bottom surface 223 of base ring 220 contacts upward-facing surface 394 of flow control ring 390, and can be moved or slid along upward-facing surface 394 of flow control ring 390 until chamfer surface 225 and/or radially-inward surface 226 of base ring 220 contacts ring chamfer surface 395 and/or outer side surface 393 of flow control ring 390, respectively.

Seal devices 500A and 500B can comprise a spring (similar to spring 440 of seal device 400) comprising a plurality of concertinaed plates 550 (similar to concertinaed plates 450). Seal device 500A can comprise spring 540A, and seal device 500B can comprise spring 540B. Spring 540A can span (e.g., in the direction of compression or expansion of spring 540) between first concertinaed plate 542 and a terminal concertinaed plate 544A. First concertinaed plate 542 can couple to base ring 520. Terminal concertinaed plate 544A can couple to and/or engage with (i.e., disposed against) a spacer plate to form a substantial seal therewith (e.g., in response to susceptor translating upward to cause contact between seal device 500A and the spacer plate and/or compression of spring 540A). Springs 540A and 540B can comprise inner diameter 541. Inner diameter 541 can be radially outward of inner diameter 521 of base ring 520, e.g., separated by radial gap 533.

Each concertinaed plate 550 can span between an inner end 552 and an outer end 554, and between inner diameter 521 and outer diameter 529 of base ring 420. Inner end 552 and/or outer end 554 of each concertinaed plate 550 can comprise a flat end (e.g., inner flat end 556 or outer flat end 557), which can facilitate coupling to other concertinaed plates (or the respective flat end(s) thereof) and/or a base ring, and/or can facilitate engagement with a spacer plate to form a substantial seal therewith.

In various examples, base ring 520 can comprise a coupling protrusion 530 protruding from top surface 524. Coupling protrusion 530 can extend from base ring 520 in the direction of compression or expansion of spring 540. First concertinaed plate 542 can couple to coupling protrusion 530 (e.g., at a peak or apex of coupling protrusion 530). Coupling protrusion 530 can comprise a coupling surface 534 to which first concertinaed plate 542 can couple. Coupling surface 534 can be at least partially flat to facilitate coupling with the flat end of inner end 552 of first concertinaed plate 542. That is, coupling surface 534 can have a surface that is complementary (including complementary shape, dimension, texture, and/or the like) to the surface of inner end 552 of first concertinaed plate 542 to facilitate coupling therebetween. First concertinaed plate 542 can be (fixedly) coupled to coupling protrusion 530 in any suitable manner, such as welding, adhesive, mechanical coupling, fastener(s), and/or the like. Coupling protrusion 530 can be disposed on top surface 524 more proximate to base inner diameter 521 than base outer diameter 529. Coupling protrusion 530 can be disposed on top surface 524 radially inward from base inner diameter 521 and can be separated from base inner diameter 521 by radial gap 533.

A surface between radial gap 533 and radially-inward surface 526 of base ring 520 can comprise an angled surface 527. Angled surface 527 can comprise an angle similar to that of chamfer surface 525. Angled surface 527 can be configured to provide a more gradual surface that can contact the susceptor or flow control ring (e.g., rather than a sharper corner between radial gap 533 and radially-inward surface 526 that could cause scraping, chipping, or other damage to the susceptor or flow control ring).

Coupling protrusion 530 can have a substantially flat or vertical radially-inward surface (wherein “substantially” within plus or minus 20 degrees from flat or vertical). Coupling protrusion 530 can have a sloped or angled radially-outward surface that tapers downward toward top surface 524 of base ring 520 in the radially-outward direction. The tapered radially-outward surface of coupling protrusion 530 can allow access to the coupling point between coupling protrusion 530 and first concertinaed plate 542 (e.g., to allow tools for coupling, decoupling, or maintaining the components). The radially-inward surface of coupling protrusion 530 can comprise access recess 532 recessed therein. Access recess 532 can be recessed into the radially-inward surface of coupling protrusion 530 proximate coupling surface 534 to allow access to the coupling point between coupling protrusion 530 and first concertinaed plate 542 (e.g., to allow tools for coupling, decoupling, or maintaining the components).

With additional reference to FIG. 5B, spring 540B can span (e.g., in the direction of compression or expansion of spring 540B) between first concertinaed plate 542 and a terminal concertinaed plate 544B. Terminal concertinaed plate 544B can be coupled to second base ring 560 in the same or similar manner as first concertinaed plate 542 coupling to base ring 520. Thus, spring 540B (and concertinaed plates 550 comprised therein) can span between base ring 520 and second base ring 560.

Second base ring 560 (an example of second base ring 460) can have the same or similar structure to that of base ring 520 (e.g., and/or be a mirror image of base ring 520). Second base ring 560 can span radially between a radially-inward surface 566 and a radially-outward surface 568, and can comprise a height spanning between top surface 563 and a bottom surface 564. Top surface 563 can be disposed against a downward-facing surface of the spacer plate in response to the susceptor translating upward and/or spring 540B being compressed. Thus, second base ring 560 can contact the spacer plate, creating a substantial seal therewith. Radially-inward surface 566 of second base ring 560 can be disposed proximate to and/or against an outer side surface of the susceptor or flow control ring. Radially-inward surface 566 of second base ring 560 can at least partially define inner diameter 521 of seal device 500B.

In various examples, second base ring 560 can comprise a chamfer surface 565 spanning between top surface 563 and radially-inward surface 566. Chamfer surface 565 can be angled (i.e., an angled bridge) between top surface 563 and radially-inward surface 566. Chamfer surface 565 can be disposed at any suitable angle, such as about 45 degrees relative to the plane along which top surface 563 spans, and/or an angle of about 135 degrees relative to top surface 563. Chamfer surface 525 can be disposed at an angle of about 45 degrees relative to the plane along which radially-inward surface 566 spans, and/or an angle of about 135 degrees relative to radially-inward surface 566 (in this context, the term “about” means plus or minus 20 or 30 degrees). Chamfer surface 565 can be configured to provide a more gradual surface that can contact the susceptor or flow control ring (e.g., rather than a sharper corner between top surface 563 and radially-inward surface 566 that could cause scraping, chipping, or other damage to the susceptor or flow control ring).

In various examples, second base ring 560 can comprise a coupling protrusion 570 protruding from bottom surface 564. Coupling protrusion 570 can extend from second base ring 560 in the direction of compression or expansion of spring 540. Terminal concertinaed plate 544B can couple to coupling protrusion 570 (e.g., at a peak or apex of coupling protrusion 570). Coupling protrusion 570 can comprise a coupling surface 574 to which terminal concertinaed plate 544B can couple. Coupling surface 574 can be at least partially flat to facilitate coupling with the flat end of inner end 552 of terminal concertinaed plate 544B. That is, coupling surface 574 can have a surface that is complementary (including complementary shape, dimension, texture, and/or the like) to the surface of inner end 552 of terminal concertinaed plate 544B to facilitate coupling therebetween. Terminal concertinaed plate 544B can be (fixedly) coupled to coupling protrusion 570 in any suitable manner, such as welding adhesive, mechanical coupling, a fastener(s), and/or the like. Coupling protrusion 570 can be disposed on bottom surface 564 more proximate to base inner diameter 521 than base outer diameter 529. Coupling protrusion 570 can be disposed on bottom surface 564 radially inward from base inner diameter 521 and can be separated from base inner diameter 521 by radial gap 573.

A surface between radial gap 573 and radially-inward surface 566 of second base ring 560 can comprise an angled surface 567. Angled surface 567 can comprise an angle similar to that of chamfer surface 525. Angled surface 567 can be configured to provide a more gradual surface that can contact the susceptor or flow control ring (e.g., rather than a sharper corner between radial gap 573 and radially-inward surface 566 that could cause scraping, chipping, or other damage to the susceptor or flow control ring).

Coupling protrusion 570 can have a substantially flat or vertical radially-inward surface (wherein “substantially” within plus or minus 20 degrees from flat or vertical). Coupling protrusion 570 can have a sloped or angled radially-outward surface that tapers upward toward top surface 563 of second base ring 560 in the radially-outward direction. The tapered radially-outward surface can allow access to the coupling point between coupling protrusion 570 and terminal concertinaed plate 544B (e.g., to allow tools for coupling, decoupling, or maintaining the components). The radially-inward surface of coupling protrusion 570 can comprise access recess 572 recessed therein. Access recess 572 can be recessed into the radially-inward surface of coupling protrusion 570 proximate coupling surface 574 to allow access to the coupling point between coupling protrusion 570 and terminal concertinaed plate 544B (e.g., to allow tools for coupling, decoupling, or maintaining the components).

With reference to FIG. 3, a reactor 300 having a susceptor 330, flow control ring 390, spacer plate 370, and/or seal device 200 is illustrated. Seal device 200 is an example of seal device 500A, B and/or seal device 400, thus the description of seal devices 400 and/or 500A, B and their components can apply to seal device 200 and its components, as appropriate. Seal device comprises a base ring 220 (similar to base rings 420 and 520) and a spring 240 (similar to spring 440 and/or 540A, B) coupled to base ring 220. Base ring 220 can span radially between a radially-inward surface 226 and a radially-outward surface 228 (the radial direction being along the y-axis), and can comprise a height spanning between top surface 224 and a bottom surface 223. Bottom surface 223 can be disposed against an upward-facing surface 394 of flow control ring 390. Radially-inward surface 226 of base ring 220 can be disposed proximate to and/or against an outer side surface 393 of flow control ring 390.

Base ring 220 can comprise a chamfer surface 225 spanning between bottom surface 223 and radially-inward surface 226 (similar to chamfer surface 525). Chamfer surface 225 can be angled (i.e., an angled bridge) between bottom surface 223 and radially-inward surface 226. Chamfer surface 225 can be disposed at an angle of about 45 degrees relative to the plane along which bottom surface 223 spans, and/or an angle of about 135 degrees relative to bottom surface 223. Chamfer surface 225 can be disposed at an angle of about 45 degrees relative to the plane along which radially-inward surface 226 spans, and/or an angle of about 135 degrees relative to radially-inward surface 226 (in this context, the term “about” means plus or minus 20 or 30 degrees). Chamfer surface 225 can be configured to provide a more gradual surface that can contact the susceptor or flow control ring (e.g., rather than a sharper corner between bottom surface 223 and radially-inward surface 226 that could cause scraping, chipping, or other damage to the susceptor or flow control ring).

Flow control ring 390 can comprise a ring chamfer surface 395 spanning between outer side surface 393 and upward-facing surface 394 of flow control ring 390. Ring chamfer surface 395 can be complementary to chamfer surface 225 of base ring 220 (e.g., in dimensions, texture, and/or any other suitable characteristics), and can comprise an angle that is complementary to the angle of chamfer surface 225 of base ring 220. The complementary nature of ring chamfer surface 395 of flow control ring 390 and chamfer surface 225 of base ring 220 can facilitate chamfer surface 225 of base ring 220 being disposed proximate and/or against ring chamfer surface 395 of flow control ring 390, such that the two surfaces, and the surrounding angles, mate and fit within and against one another. That is, the angle formed by ring chamfer surface 395 and upward-facing surface 394 flow control ring 390 can mate with the angle formed by bottom surface 223 and chamfer surface 225 of base ring 220, and the angle formed by ring chamfer surface 395 and outer side surface 393 of flow control ring 390 can mate with the angle formed by radially-inward surface 226 and chamfer surface 225 of base ring 220.

As shown in FIG. 3, and discussed in relation to the seal devices disclosed herein, the inner diameter of base ring 220 is smaller than the inner diameter of spring 240. Thus, the inner diameter of base ring 220 contacts flow control ring 390, and prevents contact of flow control ring 390 with spring 240 (e.g., to mitigate the risk of damage to spring 240).

In various examples, a seal device and its components (e.g., base ring(s) and/or spring(s)) can comprise a shape that surrounds the susceptor in a reaction chamber. For example, seal device 200 (including base ring 220 and spring 240) in FIG. 3 can span all the way around susceptor 330. In various examples, a spring can be disposed at one or more points around the susceptor, such that the force on the susceptor that creates a seal in the reaction chamber may occur at multiple points around the susceptor.

In operation, susceptor 330 in reactor 300 can translate along the x-axis from a lower position to a raised position. In various examples, susceptor 330 may not be in contact with flow control ring 390 in the lower position. In various examples, flow control ring 390 and/or seal device 200 can translate with susceptor 330. As susceptor 330 translates upward and contacts/engages with (and/or applying upward force to) flow control ring 390, spring 240 of seal device 200 can be compressed from a relaxed or expanded position to a compressed position between flow control ring 390 and spacer plate 370. Spring 240 can be biased toward an uncompressed (expanded) or less compressed position. Spacer plate 370, and/or the portion thereof protruding from a chamber sidewall, may be substantially static (i.e., spacer plate 370 and portions thereof do not move in response to a force by spring 240). In response to compression of spring 240, spring 240 can exert an upward force on downward-facing surface 374 of spacer plate 370, and/or a downward force on upward-facing surface 394 of flow control ring 390. As shown in FIG. 3, the downward force of spring 240 causes a downward force from base ring 220 onto upward-facing surface 394 of flow control ring 390. In response, flow control ring 390 may exert a downward force on upward facing surface 337 of susceptor 330. In various examples, the upward-facing surface of the susceptor receiving the downward force from the spring and/or flow control ring may be comprised on a substrate support surface of the susceptor. The downward force of flow control ring 390 on susceptor 330 can cause a substantial seal between flow control ring 390 and susceptor 330. The downward force on upward-facing surface 394 of flow control ring 390 can cause a substantial seal between flow control ring 390 and seal device (e.g., via base ring 220 and bottom surface 223 thereof). The upward force on downward-facing surface 374 of spacer plate 370 can cause a substantial seal between spacer plate 370 and seal device and/or spring 240 thereof. In examples in which a seal device includes a second base ring (e.g., second base ring 460 and/or 560) coupled to the spring (e.g., to the other end of spring 240, opposite base ring 220), the upward force from a top surface of the second base ring on downward-facing surface 374 of spacer plate 370 can cause a substantial seal between spacer plate 370 and the seal device (e.g., via the second base ring and the top surface thereof). Thus, reaction space 312 and lower chamber space 314 can be substantially fluidly separate.

In response to susceptor 330 translating from the raised position to another lower position, spring 240 can expand, thus decreasing the force between components described above. In response, reaction space 312 and lower chamber space 314 can be in fluid communication.

In various examples, the components of a seal device can be made of or and/or comprise any suitable material. The spring and its components can comprise a metal (e.g., an elemental metal) or metal alloy, such as stainless steel, nickel, nickel alloy, Hastelloy, and/or the like. The base ring(s) can comprise a metal (e.g., an elemental metal) or metal alloy, such as stainless steel, nickel, nickel alloy, Hastelloy, and/or the like. In various examples, the spring and the base ring(s) can comprise and/or be made of the same material(s).

A base ring of a seal device can comprise a substantially larger weight and/or mass than the spring of the seal device. For example, a base ring can comprise a mass that is at least three to five times greater, at least two or three or five times greater, or about three or five times greater than a mass of the spring (“about” in this context means within 10% or 20% of the respective values). A spring can comprise a mass of 150 to 200 grams or about 180 grams, while a base ring can comprise a mass of 800 to 1000 grams or about 880 or 900 grams (“about” in this context means plus or minus 50 grams).

A seal device having one or more base rings can be configured to protect the spring coupled thereto from damage. The base rings can comprise a large and/or solid block of material relative to the spring, and the base rings can be configured to contact the components of the sealing system and/or reactor system. The contact between the base ring(s) and the components of the sealing system and/or reactor system can be configured to prevent contact between the spring and such components of the sealing system and/or reactor system, to mitigate the risk of damage to the spring from such contact (the spring can be more fragile than the base ring(s)). The relatively large base rings also facilitate handling of a seal device, as a user can grab a base ring, rather than the spring, without worry about damaging, warping, and/or bending the spring, or otherwise unintentionally modifying the seal device such that the spring may not function property to create the desired substantial seal. Thus, the seal device can be removed and/or replaced between the spacer plate and the flow control ring, and/or between the spacer plate and the susceptor.

Additionally, the substantially flat surfaces provided by the base ring(s) of the seal device can facilitate greater contact between the seal device and the components in contact therewith. Similarly, the flat end of the concertinaed plates of the spring in a seal device can facilitate greater contact between concertinaed plates, the concertinaed plates and a base ring(s), and/or between a concertinaed plate and a spacer plate. Thus, such greater contact (e.g., via more surface area of contact from the flat surfaces of the various components) can result in greater sealing capabilities to achieve the desired substantial seal.

The examples of the disclosure described above do not limit the scope of the claimed subject matter, since these are merely examples. The invention is defined by the appended claims and their legal equivalents. Any equivalent embodiments are intended to be within the scope of this disclosure. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A reactor, comprising:
a reaction chamber volume enclosed within a reaction chamber;
a susceptor configured to translate up and down along an axis within the reaction chamber;
a reaction space above the susceptor within the reaction chamber volume;
a lower chamber space below the susceptor within the reaction chamber volume; and
a sealing system causing the reaction space and the lower chamber space to be substantially fluidly separate, wherein the sealing system comprises:
a spacer plate surrounding the susceptor; and
a seal device coupled to the susceptor and the spacer plate, wherein the seal device comprises a base ring coupled to the susceptor and a spring coupled to the base ring,
wherein the spring has a bias toward a compressed position or an extended position, such that the spring bias facilitates creation of a substantial seal between the spacer plate and the susceptor, causing the reaction space and the lower chamber space to be substantially fluidly separate as the susceptor moves up and down within the reaction chamber.

2. The reactor of claim 1, wherein the sealing system further comprises a flow control ring disposed around the susceptor and disposed between the susceptor and the spacer plate, wherein the seal device is disposed between the flow control ring and the spacer plate such that the seal device is coupled to the susceptor via the flow control ring, wherein the substantial seal between the spacer plate and the susceptor is facilitated by the spring bias between the flow control ring and the spacer plate.

3. The reactor of claim 2, wherein the seal device is disposed between an upward-facing surface of the flow control ring and a downward-facing surface of the spacer plate.

4. The reactor of claim 3, wherein the spring is biased toward the extended position, such that a downward force from the spring is applied to the flow control ring, which creates a downward force on the susceptor, such that a substantial seal is formed between the flow control ring and the susceptor, forming the substantially fluid separateness between the reaction space and the lower chamber space.

5. The reactor of claim 3, wherein the spring is fixedly coupled to the base ring.

6. The reactor of claim 5, wherein the seal device surrounds the susceptor, wherein the spring comprises a plurality of concertinaed plates comprising a first concertinaed plate and a terminal concertinaed plate, and wherein each concertinaed plate spans between the flow control ring and the spacer plate.

7. The reactor of claim 6, wherein the base ring comprises a base inner diameter most proximate to the susceptor, wherein the spring comprises a spring inner diameter most proximate to the susceptor, wherein the base inner diameter is more proximate to the susceptor than the spring inner diameter.

8. The reactor of claim 7, wherein the base ring comprises a bottom surface disposed against the upward-facing surface of the flow control ring and a radially-inward surface disposed against an outer side surface of the flow control ring, wherein the base ring further comprises a chamfer surface spanning between the bottom surface and the radially-inward surface of the base ring.

9. The reactor of claim 8, wherein the flow control ring further comprises a ring chamfer surface spanning between the upward-facing surface and the outer side surface that is complementary to the chamfer surface of the base ring.

10. The reactor of claim 6, wherein the base ring comprises a top surface and a coupling protrusion protruding upward from the top surface, wherein the first concertinaed plate of the concertinaed plates is coupled to the coupling protrusion.

11. The reactor of claim 10, wherein the first concertinaed plate comprises a flat end surface that is coupled to the coupling protrusion.

12. The reactor of claim 11, wherein the base ring comprises a base inner diameter most proximate to the susceptor, wherein the coupling protrusion is disposed proximate the base inner diameter.

13. The reactor of claim 11, wherein the terminal concertinaed plate is coupled to or disposed against the spacer plate.

14. The reactor of claim 11, wherein the seal device further comprises a second base ring coupled to the terminal concertinaed plate, such that the spring spans between the base ring and the second base ring.

15. The reactor of claim 14, wherein the second base ring contacts the spacer plate to create a substantial seal between the second base ring and the spacer plate.

16. The reactor of claim 1, wherein the base ring has a mass that is at least three times a mass of the spring.

17. A seal device for a reactor, comprising:
a base ring; and
a spring fixedly coupled to and extending from the base ring, wherein the spring comprises a plurality of concertinaed plates spanning between a first concertinaed plate and a terminal concertinaed plate, and
wherein the base ring comprises a base inner diameter, wherein the spring comprises a spring inner diameter, wherein the base inner diameter is more radially inward than the spring inner diameter.

18. The seal device of claim 17, wherein the base ring comprises a bottom surface, a radially-inward surface, and a chamfer surface spanning between the bottom surface and radially-inward surface of the base ring.

19. The seal device of claim 17, wherein the base ring comprises a top surface and a coupling protrusion protruding from the top surface, wherein the first concertinaed plate of the concertinaed plates comprises a flat end surface that is coupled to the coupling protrusion.

20. A sealing system for a reactor, comprising:
a spacer plate configured to surround a susceptor;
a flow control ring configured to surround the susceptor and be disposed between the spacer plate and the susceptor; and
a seal device, comprising:
a base ring; and
a spring fixedly coupled to and extending from the base ring, wherein the spring comprises a plurality of concertinaed plates comprising a first concertinaed plate and a terminal concertinaed plate, wherein the base ring and the spring span between an upward-facing surface of the flow control ring and a downward-facing surface of the spacer plate, and
wherein the spring comprises a spring bias to an extended position configured to create a substantial seal between the flow control ring and the spacer plate.
